(19) United States
(12) Patent Application Publication
(10) Pub. No.: US 2006/0103415 A1
(43) Pub. Date: May 18, 2006

(54) Array substrate inspecting method and array substrate inspecting device

(76) Inventor: Satoru Tomita, Kawagoe-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/292,374

(22) Filed: Dec. 2, 2005

Related U.S. Application Data
(63) Continuation of application No. PCT/JP04/07984, filed on Jun. 2, 2004.

(30) Foreign Application Priority Data
Jun. 4, 2003 (JP) 2003-159435

(51) Int. Cl. G01R 31/00

(52) U.S. Cl. 324/770

(57) ABSTRACT

A method of inspecting an array substrate comprising inspecting the drive circuit unit by supplying an electric signal to the drive circuit unit while the array substrate is placed in a tester chamber, and by detecting the electric signal that flowed through the drive circuit unit, and irradiating an electron beam to the pixel electrode charged with an electrical charge, and inspecting the pixel electrode based on a data of a secondary electron emitted from the pixel electrode.

### CROSS-REFERENCE TO RELATED APPLICATIONS

This is a Continuation Application of PCT Application No. PCT/JP2004/007984, filed Jun. 2, 2004, which was published under PCT Article 21(2) in Japanese.

This application is based upon and claims the benefit of priority from prior Japanese Patent Application No. 2003-159435, filed Jun. 4, 2003, the entire contents of which are incorporated herein by reference.

### BACKGROUND OF THE INVENTION

1. Field of the Invention

The present invention relates an array substrate inspecting method of inspecting an array substrate, which is a structural part of a liquid crystal display panel, and an array substrate inspecting device.

2. Description of the Related Art

Liquid crystal display panels are used in various sections of devices such as a display unit of a notebook personal computer (notebook PC), a display unit of a mobile telephone and a display unit of a television set. A liquid crystal display panel includes an array substrate in which a plurality of pixel electrodes are arranged in matrix, an opposite substrate including opposite electrode that respectively face the plurality of pixel electrodes, and a liquid crystal layer held between the array substrate and opposite substrate.

The array substrate includes a plurality of pixel electrodes arranged in matrix, a plurality of scanning lines arranged respectively along with rows of the pixel electrodes, a plurality of signal lines arranged respectively along with columns of the pixel electrodes and a plurality of switching elements each arranged in a vicinity of a crossing position where each scanning line and each signal line intersect.

There are two types of array substrates, namely a array substrate in which its switching elements are thin film transistors each using an amorphous silicon semiconductor thin film and another array substrate in which its switching elements are thin film transistors each using a polysilicon semiconductor thin film. The carrier mobility of Polysilicon is higher than that of amorphous silicon. It should be noted here that the polysilicon type array substrate can contain not only switching elements for pixel electrodes, but also scanning line drive circuit and signal line drive circuit built in there.

Array substrates described above undergo an inspection step in their production process in order to inspect them for defects. Examples of the inspection method and inspection device are discussed in Jpn. Pat. Appln. KOKAI Publication No. 11-271177, Jpn. Pat. Appln. KOKAI Publication No. 2000-3142 and U.S. Pat. No. 5,268,638.

Jpn. Pat. Appln. KOKAI Publication No. 11-271177 discloses a technique of inspecting amorphous type LCD substrates, which involves a characteristic point defect inspection process. This technique is based on the following mechanism. That is, direct light of DC component is applied on an entire surface of an LCD substrate, and as the amorphous silicon film senses the light, it becomes conductive. Here, the states of defect can be judged by detecting the amount of leak of charge accumulated in the auxiliary capacitor. The technique disclosed in Jpn. Pat. Appln. KOKAI Publication No. 2000-3142 utilizes such mechanism that when an electron beam is irradiated on a pixel electrode, the amount of the secondary electron emitted is proportional to the voltage applied to the thin film transistor. The technique of U.S. Pat. No. 5,268,638, as well, utilizes the secondary electron emitted when an electron beam is irradiated on a pixel electrode.

The product price of a liquid crystal display panel is greatly dependent on the cost of the production facilities and production time. The above-described inspection method and inspection device are essential to the production facilities. Further, it is natural that the inspection time taken up by the inspection device has an influence on the product price.

The present invention has been proposed in the light of the above-described point, and the object thereof is to provide a method of inspecting an array substrate, which can shorten the inspection time and reduce the inspection facilities, and a device for inspecting an array substrate.

### BRIEF SUMMARY OF THE INVENTION

In order to achieve the above-described object, there is provided, according to an aspect of the present invention, a method of inspecting an array substrate which comprises a substrate, a scanning line formed on the substrate, a signal line formed to intersect the scanning line, a switching element formed in a vicinity of an intersection of the scanning line and signal line, a pixel electrode connected to the switching element, and a drive circuit unit built on the substrate and including at least one of a scanning line driving circuit configured to supply a drive signal to the scanning line and a signal line driving circuit configured to supply a drive signal to the signal line, the method comprising: inspecting the drive circuit unit by supplying an electric signal to the drive circuit unit while the array substrate is placed in a tester chamber, and by detecting the electric signal that flowed through the drive circuit unit; and irradiating an electron beam to the pixel electrode charged with an electrical charge, and inspecting whether or not the pixel electrode properly holds the electrical charge based on a data of a secondary electron emitted from the pixel electrode.

Further, there is provided, according to another aspect of the present invention, a device for inspecting an array substrate, comprising: an inspection chamber in which an array substrate to be inspected can be placed; an electron beam irradiating unit configured to irradiate an electron beam to the array substrate; a first detector configured to detect a secondary electron emitted from the array substrate; an electric signal supplying unit configured to supply an electric signal to the array substrate; and a second detector configured to detect an electric signal that flew through the array substrate.

Additional advantages of the invention will be set forth in the description which follows, and in part will be obvious from the description, or may be learned by practice of the invention. The advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a flowchart designed to illustrate the method of inspecting an array substrate;

FIG. 2 is a diagram schematically showing a cross section of a liquid crystal display panel comprising an array substrate;

FIG. 3 is a perspective view of a part of the liquid crystal display panel shown in FIG. 2;

FIG. 4 is a plan view illustrating an example of an arrangement of array substrates constituted with use of a mother substrate;

FIG. 5 is a plan view schematically showing a main region of an array substrate shown in FIG. 4;

FIG. 6 is an enlarged plan view schematically showing a part of a pixel region of the array substrate shown in FIG. 5;

FIG. 7 is a diagram schematically showing a cross section of a liquid crystal display panel comprising the array substrate shown in FIG. 6;

FIG. 8 is a structural diagram schematically showing an inspection apparatus for array substrates, which includes an electric tester and electron beam tester;

FIG. 9 is a plan view showing an example of an end portion of an array substrate to be inspected; and

FIG. 10 is a plan view schematically showing a remodeled example of the main region of the array substrate.

### DETAILED DESCRIPTION OF THE INVENTION

Embodiments of the array substrate inspecting method and inspection device according to the present invention will now be described in detail with reference to accompanying drawings. First, a liquid crystal display panel including polysilicon type array substrates will be explained. In this embodiment, a polysilicon type array substrate will be described as an array substrate 101.

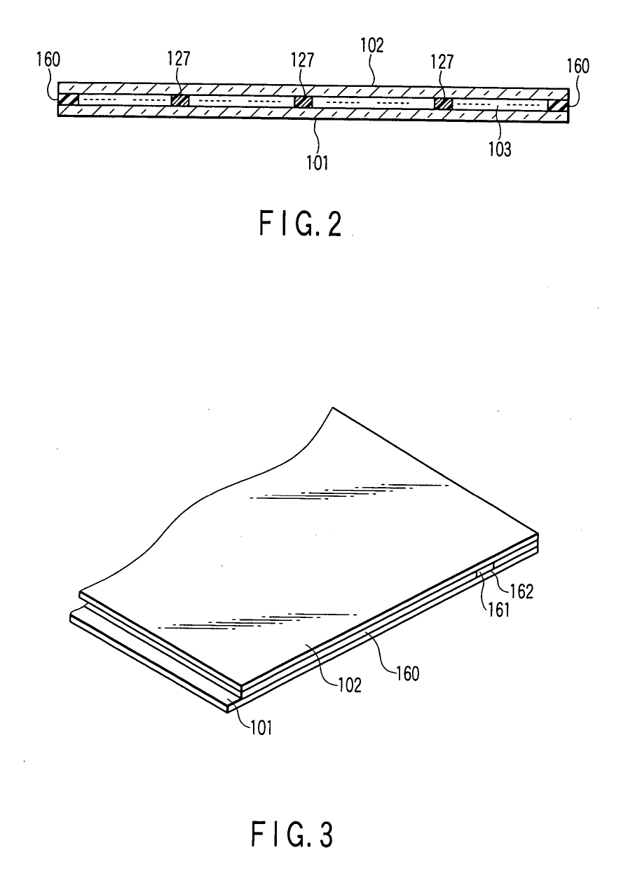

As shown in FIGS. 2 and 3, the liquid crystal display panel includes an array substrate 101, an opposite substrate 102 arranged opposite to the array substrate with a predetermined gap kept between them, and a liquid crystal layer 103 interposed between these substrates. The array substrate 101 and opposite substrate 102 have a predetermined gap kept between them by means of a columnar spacer 127 serving as a spacer. The peripheral portions of the array substrate 101 and opposite substrate 102 are bonded together with a sealing material 160. A liquid crystal inlet 161 that is formed in a part of the sealing material is sealed with a sealant 162.

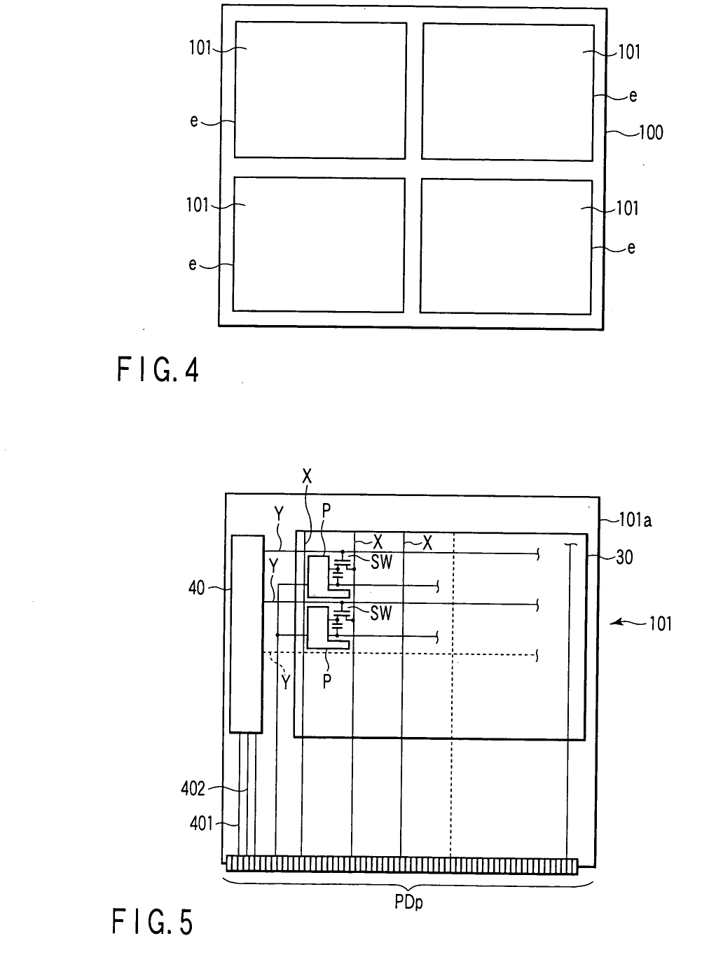

Next, with reference to FIG. 4, the array substrate 101 will be explained. FIG. 4 shows a mother substrate 100 that serves as a substrate having larger dimensions than those of the array substrate, and the figure illustrates an example in which four array substrates 101 are structured with use of the mother substrate. In this manner, array substrates 101 are formed generally with use of the mother substrate 100.

Next, the structure of the array substrate 101 will now be described by focusing on one array substrate 101 shown in FIG. 4 as a typical example. The array substrate 101 includes an array substrate main region 101a and an array substrate sub-region 101b. Here, the array substrate main region 101a will be described in detail. A detailed explanation of the array substrate sub-region 101b will be provided later.

As shown in FIG. 5, a plurality of pixel electrodes P are arranged in matrix in a pixel region 30 on the array substrate 101. The array substrate 101 includes, in addition to pixel electrodes P, a plurality of scanning lines Y arranged along the rows of these pixel electrodes P and a plurality of signal lines X arranged along the columns of these pixel electrodes P. The array substrate 101 further includes thin film transistors (to be abbreviated as TFT hereinafter) SW each serving as a switching element arranged in the vicinity of an intersection of a scanning line Y and a signal line X. The array substrate 101 includes a scanning line driving circuit 40 that serves to drive a plurality of scanning lines Y, as a drive circuit unit.

Each TFT SW, when it is driven by a respective scanning line Y, applies a signal voltage of a respective signal line X to a respective pixel electrode P. The scanning line driving circuit 40 is built on the array substrate 101 and is located in an outer region of the pixel region 30. The scanning line driving circuit 40 is made of TFTs each containing a polysilicon semiconductor film, as in the case of the TFT SW.

Further, the array substrate 101 includes a pad group PDp further including a plurality of terminals that are arranged along one side of an edge line of the array substrate main region 101a and are connected to the scanning line driving circuit 40 and signal lines X. The pad group PDp is used to, in addition to the reception of various types of signals, but also input and output an inspection signal. Each array substrate 101 is obtained, for example, by cutting the mother substrate 100 along an edge e (see FIG. 4) of the respective array substrate to separate it from the others.

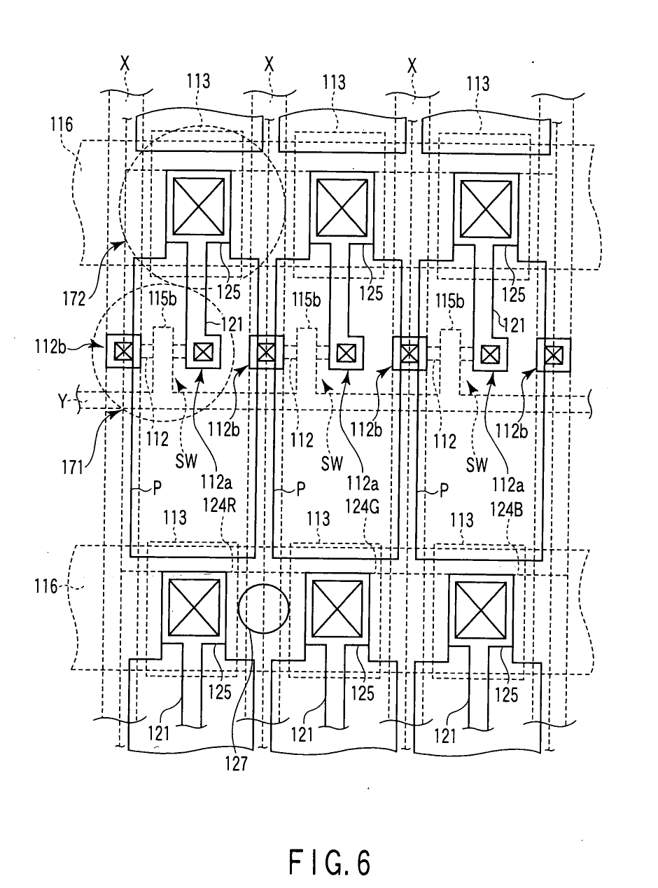

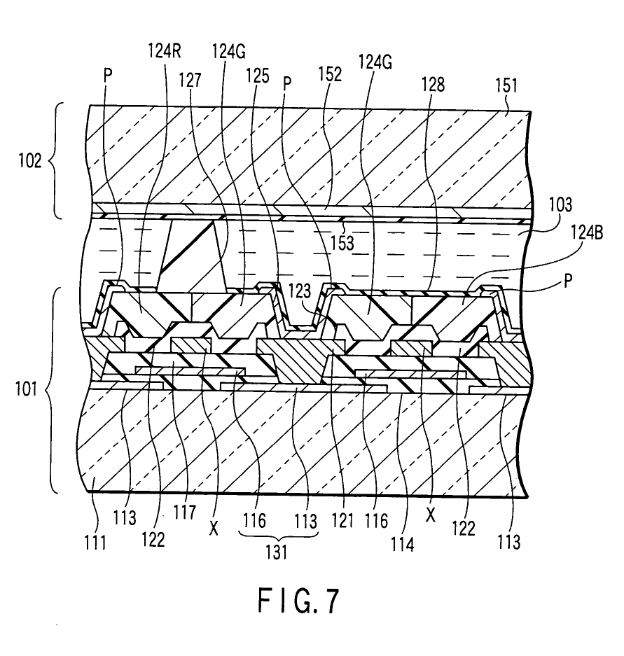

Next, with reference to FIGS. 6 and 7, a part of the pixel region 30 of the liquid display panel is focused for further explanation. FIG. 6 is an enlarged plan view schematically showing the pixel region 30 of an array substrate, and FIG. 7 is an enlarged cross sectional view of the pixel region of the liquid crystal display panel. As shown, the array substrate 101 includes a substrate 111 that is a transparent insulating substrate such as a glass plate. On the substrate 111, a plurality of signal lines X and a plurality of scanning lines Y are arranged in matrix, and TFTs SW are provided in the vicinity of each intersection of signal lines and scanning lines (See the section surrounded by a circle 171 in FIG. 6).

Each TFT SW includes a semiconductor film 112 having source/drain regions 112a and 112b made of polysilicon and a gate electrode 115b, which is an extension of a part of the respective scanning line Y.

On the substrate 111, a plurality of auxiliary capacitor lines 116 are arranged in stripe to form an auxiliary capacitor element 131, and they are extended in parallel with the scanning lines Y. A pixel electrode P is formed in this section. (See FIG. 6, the section surrounded by a circle 172 and FIG. 7.)

In more detail, on the substrate 111, the semiconductor film 112 and auxiliary capacitor lower electrodes 113 are formed, and further, a gate insulating film 114 is formed on the substrate that includes these semiconductor film and auxiliary capacitor lower electrodes. The auxiliary capacitor lower electrodes 113 are formed of polysilicon as in the case of the semiconductor film 112. On the gate insulating film 114, scanning lines Y, gate electrodes 115b and auxiliary capacitor lines 116 are arranged. An auxiliary capacitor line 116 and an auxiliary capacitor lower electrode 113 are arranged to face each other via the gate insulating film 114. An interlayer insulating film 117 is formed on the gate insulating film 114 that includes the scanning lines Y, gate electrodes 115b and the auxiliary capacitor lines 116.

Contact electrodes 121 and signal lines X are formed on the interlayer insulating film 117. Each contact electrode 121 is connected via a respective contact hole to the source/drain region 112a of the respective semiconductor film 112 and the pixel electrode P. The contact electrode 121 is connected to the auxiliary capacitor lower electrode 113. Each signal line X is connected to the source/drain region 112b of the respective semiconductor film 112 via a respective contact hole.

A protective insulating film 122 is formed to overlay on each of the contact electrodes 121, signal lines X and interlayer insulating film 117. On the protective insulating film 112, green coloring layers 124G, red coloring layers 124R and blue coloring layers 124B, which are formed in stripe, are arranged alternately to be adjacent to each other. The coloring layers 124G, 124R and 124B form a color filter.

The pixel electrodes P are formed on their respective coloring layers 124G, 124R and 124B by transparent conductive film such as ITO (indium tin oxide). Each pixel electrode P is connected to the respective contact electrode 121 via a contact hole 125 formed in the coloring layers and protective insulating film 122. The peripheral portion of the pixel electrode P is formed to overlay on an auxiliary capacitor line 116 and signal line X. The auxiliary capacitor element 131 connected to the pixel electrode P functions as auxiliary capacitor store electric charge.

A columnar spacer 127 (see FIG. 6) is formed on the coloring layers 124R and 124G. Although the figure does not show all of them, a plurality of columnar spacers 127 are formed on each of the coloring layers at a predetermined density. An alignment film 128 is formed on the coloring layers 124G, 124R and 124B and the pixel electrodes P.

The opposite substrate 102 includes a substrate 151 which is a transparent insulating substrate. An opposite electrode 152 and an alignment film 153, which are made of a transparent material such as ITO, are formed in this order on the substrate 151.

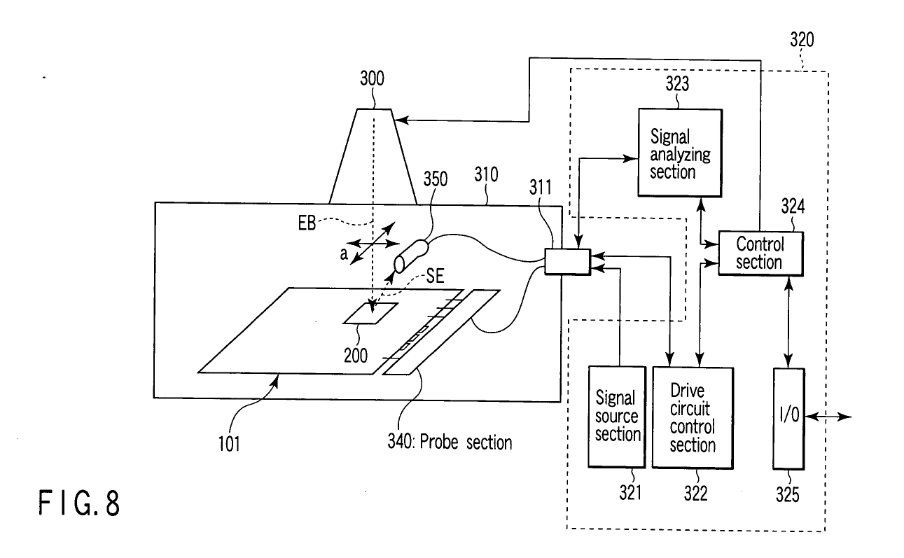

The inspection method for an array substrate 101, as well as the array substrate inspection device, which use an electron beam tester (to be called “EB tester” hereinafter) and electric tester, will now be described with reference to FIG. 8. It should be noted that the inspection is carried out after forming the pixel electrode P on the substrate.

First, the structure of the inspection device used for the inspection of the array substrate 101 will now be described. The inspection device is equipped with an electric tester and EB tester as an integral body. A vacuum chamber 310 serving as an inspection chamber is equipped with an electron beam scanner 300. The electron beam scanner 300 functions as electron beam irradiating means for irradiating electron beams onto the array substrate. The vacuum chamber 310 has such a structure in which the array substrate to be inspected can be loaded or it can be unloaded therefrom. Further, an electron detector 350 is provided in the vacuum chamber 310. The electron detector 350 functions as electron detecting means for detecting the secondary electrons emitted from the array substrate. A probe unit 340 is arranged in the vacuum chamber 310, and the probe unit 340 can bring its probes into contact with a corresponding pad of the array substrate 101. This operation is controlled by a robot, which is not illustrated in the figure, at a high accuracy.

A sealing connector 311 is provided at a side wall of the vacuum chamber 310. The sealing connector 311 is designed to connect internal members such as the probe unit 340 and electron detector 350 to external corresponding units respectively while maintaining the airtight state inside the vacuum chamber 310. A control device 320 is provided outside the vacuum chamber 310. The control device 320 includes a signal source unit 321, a drive circuit control unit 322, a signal analyzing unit 323, a control unit 324 that controls these units, and an input/output unit 325. The signal source unit 321 functions as electric signal supplying means for supplying an electric signal to the array substrate. The signal analyzing unit 323 functions as electric signal detecting means for detecting an electric signal that flowed through the array substrate.

The control unit 324 controls the drive circuit control unit 322 and carries out the inspection of the scanning line drive circuit 40 on the array substrate 101 via the probe unit 340. Detection data used for testing the scanning line drive circuit 40 is taken from the drive circuit control unit 322 to the control unit 324, and then outputted to an external device, for example, a display device via the input/output unit 325. The drive circuit control unit 322 can drive elements on the array substrate 101 via the scanning line drive circuit 40 on the array substrate 101. At this point, a signal from the signal source unit 321 can be applied to the signal lines X on the array substrate, to realize an electric charge for the auxiliary capacitor of each pixel section 200.

The control unit 324 controls the electron beam scanner 300 to scan pixel sections 200 of the array substrate 101. During the scanning, the secondary electrons emitted from the pixel sections 200 are detected by the electron detector 350, and the detection data is sent to the signal analyzing unit 323. The signal analyzing unit 323 analyzes the detection data outputted from the electron detector 350, and refers to position data (the address of a detected pixel unit) outputted from the control unit 324 and judges the condition of the pixel sections 200.

The inspection device inspects the array substrate 101 in the following manner. That is, first, the array substrate 101 is placed in the vacuum chamber 310. Probes of the probe unit 340 are connected to the connection pad group CPDp, which will be later described. Drive signals, which are electric signals outputted from the signal source unit 321, are supplied to the connection pad group CPDp via the probe unit 340. In this manner, the drive signal are supplied to the scanning line drive circuit 40 and the signal lines X that are connected to the connection pad group CPDp. By detecting and analyzing a drive signal that flowed through the scanning line drive circuit 40, the drive circuit 40 is electrically inspected. Further, drive signals are supplied to the scanning line drive circuit 40 and the signal lines X to accumulate a charge on pixel electrodes P. Then, when a pixel electrode P is thus charged, an electron beam is irradiated from the electron beam scanner 300 to the pixel P. By detecting and analyzing the secondary electrons emitted from the pixel electrode P, the electrode P is inspected as to whether or not it properly holds the electrical charge. Thus, the inspection for the pixel electrode P is carried out at a separate time from that of the inspection for the scanning line drive circuit 40 as a drive circuit unit. This inspection includes not only inspection of a defect of the pixel electrode P itself, but also inspection of defects the elements related to the pixel electrode, such as the TFT SW connected to the pixel electrode P and the auxiliary capacitor element 131 that contains the pixel electrode P.

Alternatively, the electrical inspection of the scanning line drive circuit 40 as the drive circuit unit and the charging on the pixel electrode 40 may be carried out at the same time. That is, in order to inspect the scanning line drive circuit 40, the electric signal used to charge the pixel electrode P is utilized.

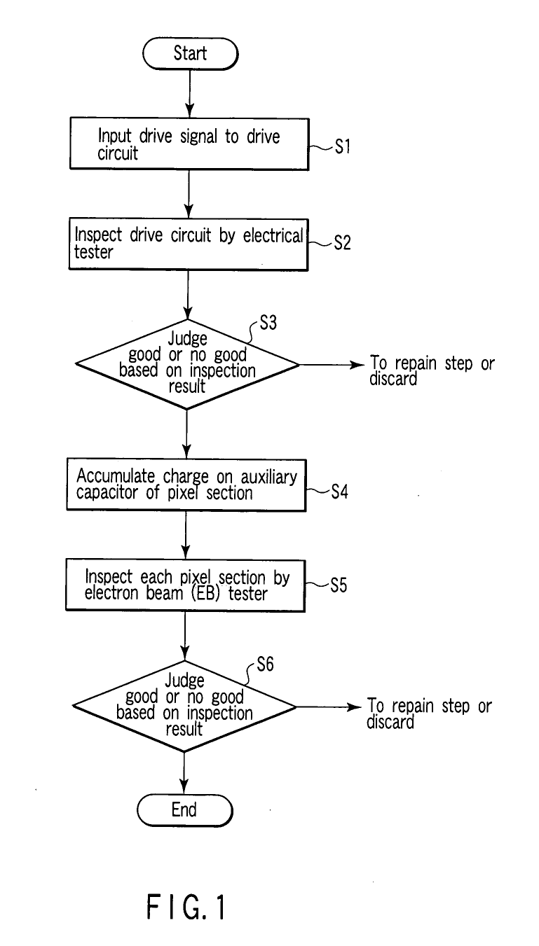

FIG. 1 schematically shows a process of inspecting the array substrate 101 as described above. In the vacuum chamber 310, a drive signal is inputted to the scanning line drive circuit 40 (Step S1). The scanning line drive circuit 40 is inspected with an electric tester (Step S2). One of the inspection items is that a start pulse is supplied to the scanning line drive circuit 40 and based on whether or not a serial output is normal, the operation of the scanning line drive circuit 40 is judged if it is normal or not (Step S3). If a defect is found at this point, it is repaired or discarded.

Next, when the operation of the scanning line drive circuit 40 is judged as being normal, the test of each pixel section 200 is started. First, the auxiliary capacitor element 131 of each pixel unit 200 is electrically charged (Step S4). The charging can be done by supplying a drive signal from the signal source unit 321 by the electric tester. Meanwhile, the electron beam scanner 300 is driven. Thus, the detection data from the electron detector 350 is sent to the signal analyzing unit 323, where the inspection of each of the pixel sections 200 is executed (Step S5). Here, the secondary electrons emitted were measured to judge if the voltage of each of the pixel sections 200 is normal or not (Step S6). When a defective array substrate is detected, it is repaired or discarded.

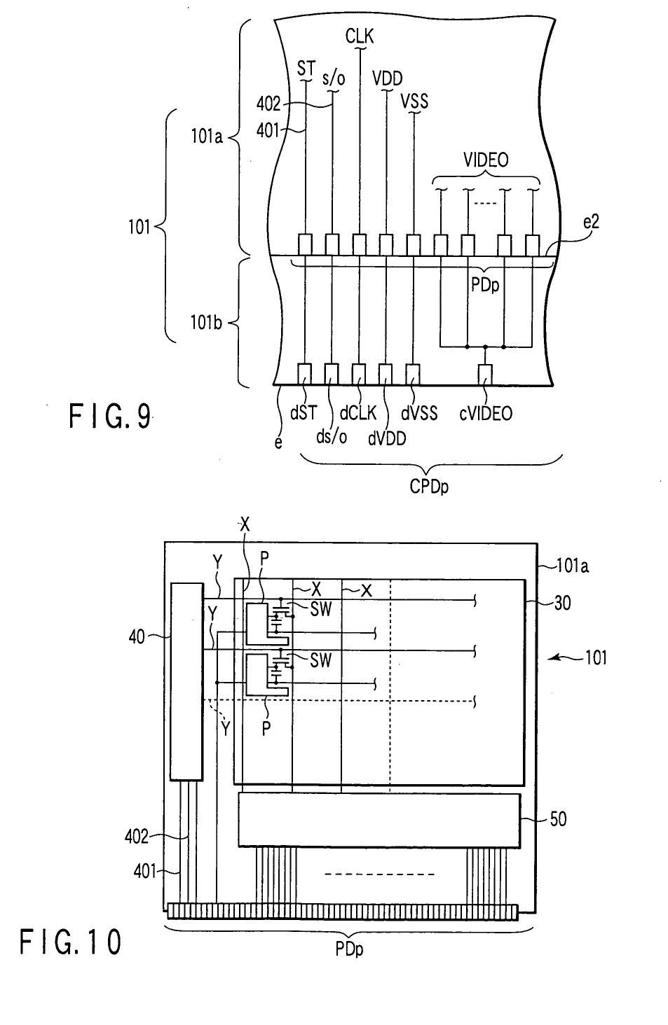

FIG. 9 shows an example of an end portion of an array substrate 101 to be inspected. The array substrate 101 includes an array substrate main region 101a and an array substrate sub-region 101b that is located on an outer side of the main region 101a. It should be noted that after the inspection, the array substrate sub-region 101b is cut off, for example, by drawing a scribe line along a cut-off line e2.

The pad group PDp of the array substrate main region 101a is connected to the scanning line driving circuit 40 and signal lines X shown in FIG. 5 via wiring lines. The types of terminals that form the pad group PDp that is located in this area can be categorized into a logic terminal, a power source terminal, an inspection terminal and a signal input terminal.

The logic terminal includes a terminal CLK and a terminal ST. Signals that are inputted to the terminal CLK and terminal ST are a clock signal and a start pulse signal. The clock signal and start pulse signal are those to be inputted to the scanning line drive circuit 40.

The inspection terminal is a serial output terminal s/o. A signal outputted from the serial output terminal s/o is a serial output signal outputted from a shift register (s/r) of the scanning line drive circuit 40 in reply to the start pulse.

There are a plurality of types of power source terminals such as a terminal VDD and terminal VSS. Signals inputted to the terminal VDD and terminal VSS are a high level power source and low level power source. The signal input terminal is a terminal VIDEO. An example of the signal to be inputted to the terminal VIDEO is a video signal. It should be noted here that the terminal VIDEO has several hundreds to several thousands terminals and it occupies a large portion of the pad group PDp.

On the other hand, the connection pad group CPDp is provided in an edge of the array substrate sub-region 101b. The connection pad group CPDp is connected to the pad group PDp on the array substrate main region 101a side via wiring lines. FIG. 9 illustrates a brief relationship between the pad group PDp and the connection pad group CPDp. For the sake of simplicity, input pads to the scanning line drive circuit 40 and input pads to scanning lines X to which video signals are inputted are illustrated.

Terminals of the connection pad group CPDp include a clock-use dependent terminal dCLK, a high-level dependent terminal dVDD, a low-level dependent terminal dVSS, an image-signal-use common terminal cVIDEO and the like. The dependent terminal dCLK, dependent terminal dVDD, dependent terminal dVSS, common terminal cVIDEO and the like are arranged in an edge e of the array substrate sub-region 101b, and they are connected to the pad group PDp of the corresponding array substrate main region 101a via wiring lines.

The above-described embodiment has such a structure in which a plurality of terminals VIDEO are connected to one common terminal cVIDEO; however the invention is not limited to this, but it may be of any structure as long as terminals VIDEO are connected to a few common terminals. In this manner, the number of pads of the connection pad group CPDp provided in the array substrate sub-region 101b is remarkably decreased as compared to the number of pads of the pad group PDp provided in the main region 101a.

Now, the electric inspection for the scanning line drive circuit 40 of an array substrate 101 having the above-described structure will now be described. When a clock signal from the dependent terminal dCLK connected to the scanning line drive circuit 40 and a start pulse from the dependent terminal dST are inputted to the scanning line drive circuit 40, a shift register that constitutes the scanning line drive circuit 40 is driven and thus an output signal from the shift register is outputted to the dependent terminal ds/o. By analyzing the output from the dependent terminal ds/o, it is judged whether or not the scanning line drive circuit 40 is proper.

Next, in order to inspect the pixel sections 200 with electron beams, the pixel electrodes P are electrically charged. Then, a clock signal and start pulse are inputted to the scanning line drive circuit 40 as in a similar manner described above, and further a high-level power source and low-level power source are inputted thereto, and thus the scanning line drive circuit 40 is driven as in the case of a regular displaying mode. Further, video signals are inputted from the terminals VIDEO to signal lines X, thereby electrically charging the pixel electrodes P. In this state, the inspection with electron beams is carried out as described before.

According to the array substrate inspection method and inspection device having the structure described above, an array substrate 101 in which a scanning line drive circuit 40 is inspected as described above. That is, the electrical inspection of the scanning line drive circuit 40 and the inspection of the pixel sections 200 with electron beams are carried out in the same chamber. Therefore, it is possible to shorten the inspection time and reduce the facilities.

This invention is not limited to the above-described embodiment, but various modifications can be made within the scope of the invention. For example, it is alternatively possible that a scanning line drive circuit 40 and a signal line drive circuit 50 that drives and a plurality of signal lines are built as a drive circuit unit in the outer region of the pixel region 30 on the array substrate 101 as shown in FIG. 10. The signal line drive circuit 50 is made with use of TFTs having polysilicon semiconductor films as in the case of the TFT SW.

The signal line drive circuit 50 is connected to the connection pad group CPDp via the pad group PDp. The connection pad group CPDp includes logic terminals, inspection terminals, etc. that are connected to the signal line drive circuit 50. When video signals, clock signal and start pulse signal are inputted to the signal line drive circuit 50, a shift register that constitutes the signal line drive circuit 50 is driven and thus an output signal from the shift register is outputted. By analyzing the output, it is judged whether or not the signal line drive circuit 50 is proper.

In the manner described above, the control unit 324 controls the drive circuit control unit 322 so as to inspect the scanning line drive circuit 40 and the signal line drive circuit 50 on the array substrate 101 via the probe unit 340. By detecting and analyzing the drive signal that flowed through the scanning line drive circuit 40 and the signal line drive circuit 50, the scanning line drive circuit 40 and the signal line drive circuit 50 can be electrically inspected.

As the drive signal is supplied to the scanning line drive circuit 40 and the signal line drive circuit 50, the pixel electrodes P can be electrically charged. Therefore, it is possible to inspect it with electron beams as described above.

As an array substrate 101 to be inspected, it suffices if the substrate includes a drive circuit unit built on the substrate and including at least one of the scanning line drive circuit 40 that supplies drive signals to scanning lines Y and the signal line drive circuit 50 that supplies drive signals to signal lines X. The TFT that constitutes the scanning line drive circuit 40 and the signal line drive circuit 50 may not be of a type using polysilicon.

What is claimed is:

1. A method of inspecting an array substrate which comprises a substrate, a scanning line formed on the substrate, a signal line formed to intersect the scanning line, a switching element formed in a vicinity of an intersection of the scanning line and signal line, a pixel electrode connected to the switching element, and a drive circuit unit built on the substrate and including at least one of a scanning line driving circuit configured to supply a drive signal to the scanning line and a signal line driving circuit configured to supply a drive signal to the signal line, the method comprising:
inspecting the drive circuit unit by supplying an electric signal to the drive circuit unit while the array substrate is placed in a tester chamber, and by detecting the electric signal that flowed through the drive circuit unit; and
irradiating an electron beam to the pixel electrode charged with an electrical charge, and inspecting whether or not the pixel electrode properly holds the electrical charge based on a data of a secondary electron emitted from the pixel electrode.

2. The inspecting method according to claim 1, wherein the inspection of the drive circuit unit and the inspection of the pixel electrode are carried out at separate times.

3. The inspecting method according to claim 1, wherein the inspection of the drive circuit unit is carried out by utilizing the electric signal used to charge the pixel electrode.

4. The inspecting method according to claim 1, wherein the switching element and the drive circuit unit each include a transistor that uses polysilicon.

5. A device for inspecting an array substrate, comprising:
an inspection chamber in which an array substrate to be inspected can be placed;
an electron beam irradiating unit configured to irradiate an electron beam to the array substrate;
a first detector configured to detect a secondary electron emitted from the array substrate;
an electric signal supplying unit configured to supply an electric signal to the array substrate; and
a second detector configured to detect an electric signal that flew through the array substrate.
